(19) United States
(12) Patent Application Publication
(10) Pub. No.: US 2016/0291099 A1
(43) Pub. Date: Oct. 6, 2016

(54) MAGNETISM DETECTION SENSOR AND MAGNETISM MEASUREMENT APPARATUS

(71) Applicant: SEIKO EPSON CORPORATION, Tokyo (JP)

(72) Inventor: Hitoshi UENO, Shiojiri-shi (JP)

(73) Assignee: SEIKO EPSON CORPORATION, Tokyo (JP)

(21) Appl. No.: 15/082,377

(22) Filed: Mar. 28, 2016

(30) Foreign Application Priority Data
Apr. 6, 2015 (JP) 2015-077457

(51) Int. Cl. G01R 33/26

(52) U.S. Cl. CPC G01R 33/26

(57) ABSTRACT

A magnetism sensor includes a magnetism reaction section having a gas cell filled with a gas that rotates the plane of polarization of laser beam passing through the magnetism reaction section in correspondence with the intensity of a magnetic vector, a light guide section that guides the laser beam to the magnetism reaction section, and a light detection section that detects the angle of rotation of the plane of polarization of the laser beam having passed through the magnetism reaction section. The light guide section and the light detection section are positionally fixed to each other, and the magnetism reaction section is so provided as to be attachable and detachable to and from the light guide section and the light detection section.

### BACKGROUND

1. Technical Field

The present invention relates to a magnetism detection sensor and a magnetism measurement apparatus.

2. Related Art

A biological magnetic field measurement apparatus for measuring a cardiac magnetic field, a cerebral magnetic field, and other biological magnetic fields, each of which is weaker than terrestrial magnetism, has been studied. The biological magnetic field measurement apparatus performs noninvasive measurement and therefore allows measurement of the state of an organ with no burden on a subject. JP-A-2012-177585 discloses a magnetism measurement apparatus that detects a weak magnetic field. According to JP-A-2012-177585, the apparatus uses an optical-pumping-type magnetism detection sensor. In the magnetism detection sensor, a gas containing an alkali metal atom is sealed in cells. The cells are irradiated with a laser beam. At this point, the orientations of magnetic moment of the alkali metal atoms are aligned with one another in each of the cells.

When magnetism acts on the magnetism detection sensor, the magnetic moment of each atom experience precession. When linearly polarized light passes through each of the cells, the precession of the magnetic moment rotates the plane of polarization of the light. Detection of the angle of rotation of the plane of polarization allows measurement of the intensity of the magnetism acting on the magnetism detection sensor. The magnetism detection sensor includes a magnetism reaction section in which the cells are arranged in a matrix. A light guide section that guides light to the cells and a light detection section that detects the angle of rotation of the plane of the polarization of the light having passed through the cells are so disposed as to spatially coincide with each other.

The gas sealed in each of the cells leaks out of the cell with time. The sensitivity of the magnetism detection sensor decreases accordingly. It is therefore necessary to refill the cells with the gas after a predetermined period has elapsed since the cells were filled with the gas. In this process, in the magnetism detection sensor disclosed in JP-A-2012-177585, the light guide section, the magnetism reaction section, and the light detection section are separated from one another. Each of the cells in the magnetism reaction section is then refilled with the gas. The light guide section, the magnetism reaction section, and the light detection section are then so assembled as to spatially coincide with one another. The optical axes of the light guide section and the light detection section are so adjusted as to be aligned with each other, and the aligned optical axes are examined. The greater the number of cells, the more difficult the task of aligning the optical axes with each other. It has therefore been desired to develop a magnetism reaction section that does not require the optical path adjustment even when the magnetism reaction section is exchanged but can readily restore the magnetism detection sensitivity.

### SUMMARY

An advantage of some aspects of the invention is to solve at least a part of the problems described above, and the invention can be implemented as the following forms or application examples.

### Application Example 1

A magnetism detection sensor according to this application example includes a magnetism reaction section having a gas chamber filled with a gas that rotates a plane of polarization of light passing through the magnetism reaction section in correspondence with intensity of magnetism, alight guide section that guides the light to the magnetism reaction section, and a light detection section that detects an angle of rotation of the plane of polarization of the light having passed through the magnetism reaction section, wherein the light guide section and the light detection section are positionally fixed to each other, and the magnetism reaction section is so provided as to be attachable and detachable to and from the light guide section and the light detection section.

According to this application example, the magnetism detection sensor includes the light guide section, the magnetism reaction section, and the light detection section. The light guide section guides light to the magnetism reaction section. The magnetism reaction section has a gas chamber, and the gas chamber is filled with a gas that rotates the plane of polarization of the light passing through the magnetism reaction section in response to magnetism. The light guided by the light guide section passes through the gas chamber. The light passing through the gas chamber reacts with magnetism, and the plane of polarization of the light rotates. The light having passed through the gas chamber is inputted to the light detection section. The light detection section detects the angle of rotation of the plane of polarization of the light. The angle of rotation of the plane of polarization of the light corresponds to the intensity of the magnetism. The intensity of the magnetism can therefore be detected from the output from the light detection section.

The magnetism reaction section is so provided as to be attachable and detachable to and from the light guide section and the light detection section. The gas with which the gas chamber is filled may leak out of the gas chamber with time in some cases. Exchange of the magnetism reaction section after a predetermined period elapses allows recovery of magnetism detection sensitivity. The light guide section and the light detection section are positionally fixed to each other. Therefore, even when the magnetism reaction section is taken out of the light guide section and the light detection section and then reinstalled, the optical path from the light guide section toward the light detection section remains unchanged. As a result, even when the magnetism reaction section is exchanged, optical path adjustment can be omitted, whereby the magnetism detection sensitivity can be readily recovered.

### Application Example 2

The magnetism detection sensor according to the application example described above may further include an accommodation section that accommodates the magnetism reaction section in an attachable and detachable manner.

According to this application example, the magnetism detection sensor further includes an accommodation section, and the accommodation section accommodates the magnetism reaction section in an attachable and detachable manner. The accommodation section provides a space in which the magnetism reaction section is disposed. Therefore, even when the magnetism reaction section is taken out, a space in which the magnetism reaction section is disposed is left. As a result, the magnetism reaction section can be readily placed in the same position from which the magnetism reaction section has been taken out.

### Application Example 3

In the magnetism detection sensor according to the application example described above, the gas chamber in the magnetism reaction section may be formed of a plurality of gas chambers, the light detection section may include a plurality of light reception devices that receive the light, the light guide section guides the light to the plurality of gas chambers, and the gas chambers and the light reception devices are arranged at the same intervals.

According to this application example, the magnetism reaction section includes a plurality of gas chambers. Further, the light detection section includes a plurality of light reception devices that receive the light. Since the light guide section guides the light to the plurality of gas chambers, the light passes through the plurality of gas chambers. Since the gas chambers and the light reception devices are arranged at the same intervals, the light beams having passed through the gas chambers can be inputted to the respective light reception devices.

### Application Example 4

In the magnetism detection sensor according to the application example described above, the light guide section and the light detection section may be so disposed that an optical axis of the light traveling from the light guide section to the magnetism reaction section and an optical axis of the light traveling from the magnetism reaction section to the light detection section coincide with each other along the same straight line.

According to this application example, the optical axis of the light traveling from the light guide section to the magnetism reaction section and the optical axis of the light traveling from the magnetism reaction section to the light detection section coincide with each other along the same straight line. The light traveling from the light guide section to the magnetism reaction section can therefore be reliably inputted to the light detection section.

### Application Example 5

In the magnetism detection sensor according to the application example described above, an attachment/detachment direction in which the magnetism reaction section is moved when the magnetism reaction section is attached or detached may be perpendicular to the optical axis of the light traveling from the light guide section to the light detection section.

According to this application example, the attachment/detachment direction is perpendicular to the optical axis of the light traveling from the light guide section to the light detection section. The magnetism reaction section can therefore be moved in the attachment/detachment direction with no change in the distance between the light guide section and the light detection section.

### Application Example 6

In the magnetism detection sensor according to the application example described above, the accommodation section may include a guide section that guides the magnetism reaction section in the attachment/detachment direction.

According to this application example, the accommodation section includes the guide section, which guides the magnetism reaction section in the attachment/detachment direction. The magnetism reaction section can therefore be readily moved in the attachment/detachment direction by use of the guide section.

### Application Example 7

In the magnetism detection sensor according to the application example described above, the guide section may extend in the attachment/detachment direction and may be formed of guide sections disposed on opposite sides of the magnetism reaction section in a direction perpendicular to the attachment/detachment direction.

According to this application example, the guide section is formed of guide sections disposed on opposite sides of the magnetism reaction section in the direction perpendicular to the attachment/detachment direction. The guide sections extend in the attachment/detachment direction. Therefore, since the magnetism reaction section is supported on opposite sides in the direction perpendicular to the attachment/detachment direction, the magnetism reaction section can be so supported as to be separate from the light guide section and the light detection section. As a result, the magnetism reaction section and the light guide section can be thermally insulated from each other, and the magnetism reaction section and the light detection section can be thermally insulated from each other.

### Application Example 8

In the magnetism detection sensor according to the application example described above, the magnetism reaction section may be positioned between the light guide section and the light detection section.

According to this application example, the light guide section, the magnetism reaction section, and the light detection section are arranged in this order. Therefore, since the three sections are arranged in the light traveling direction, no optical element that controls the passage of the light is required, whereby the magnetism detection sensor can have a high-productivity structure.

### Application Example 9

The magnetism detection sensor according to the application example described above may further include a reflection section that so reflects the light traveling from the light guide section as to cause the reflected light to travel toward the light detection section, and the reflection section, the magnetism reaction section, the light guide section, and the light detection section may be arranged in this order.

According to this application example, the light guide section guides the light to the magnetism reaction section. The light having passed through the magnetism reaction section is reflected off the reflection section and passes through the magnetism reaction section again. The light having passed through the magnetism reaction section passes through the light guide section and enters the light detection section. The magnetism reaction section rotates the plane of polarization of the light in accordance with the intensity of magnetism, and the light detection section detects the angle of rotation of the plane of polarization. The magnetism detection sensor can therefore detect the intensity of the magnetism. Further, since the light passes through the magnetism reaction section twice, the amount of effect of the magnetism on the light is doubled. The magnetism detection sensor can therefore detect the magnetism with high sensitivity.

### Application Example 10

In the magnetism detection sensor according to the application example described above, the light guide section may include a polarization conversion element that outputs linearly polarized light, the gas may contain an alkali metal, and the light detection section may include an orthogonal separation element.

According to this application example, the light guide section includes a polarization conversion element that outputs linearly polarized light. The light guide section therefore outputs linearly polarized light to the magnetism reaction section. The magnetism reaction section is filled with a gas containing an alkali metal. The magnetism reaction section can therefore rotate the plane of polarization of the light passing through the magnetism reaction section in correspondence with the intensity of magnetism. The light detection section includes an orthogonal separation element and can separate the light into two linearly polarized light beams polarized in directions perpendicular to each other. Detection of the optical intensities of the two linearly polarized light beams therefore allows detection of the angle of rotation of the plane of polarization. Since the angle of rotation of the plane of polarization corresponds to the intensity of the magnetism, the magnetism detection sensor can detect the intensity of the magnetism.

### Application Example 11

A magnetism measurement apparatus according to this application example includes a magnetism detection sensor that detects magnetism emitted from a subject and a display section that displays a state of the magnetism detected with the magnetism detection sensor, wherein the magnetism detection sensor is any one of the magnetism detection sensors described above.

According to this application example, the magnetism measurement apparatus includes the magnetism detection sensor and the display section. The magnetism detection sensor detects magnetism, and the display section displays the state of the magnetism. The magnetism detection sensor is any of the magnetism detection sensors described above. Therefore, since the magnetism measurement apparatus requires no optical axis adjustment even when the magnetism reaction section is exchanged, whereby an apparatus including a magnetism detection sensor capable of readily recovering magnetism detection sensitivity can be provided.

### BRIEF DESCRIPTION OF THE DRAWINGS

The invention will be described with reference to the accompanying drawings, wherein like numbers reference like elements.

FIG. 1 is a schematic perspective view showing the configuration of a biological magnetic field measurement apparatus according to a first embodiment.

FIG. 2A is a diagrammatic side cross-sectional view for describing the structure of the biological magnetic field measurement apparatus, and FIG. 2B is a diagrammatic side view for describing the structure of the biological magnetic field measurement apparatus.

FIGS. 3A and 3B are diagrammatic side cross-sectional views showing the structure of a table.

FIG. 4A is a schematic perspective view showing the structure of a magnetism sensor, and FIG. 4B is a schematic exploded perspective view showing the structure of the magnetism sensor.

FIG. 5A is a diagrammatic side cross-sectional view showing the structure of the magnetism sensor, and FIG. 5B is a diagrammatic side view showing the structure of the magnetism sensor.

FIG. 6A is a diagrammatic transparent side view showing the structure of the magnetism sensor, and FIG. 6B is a diagrammatic plan view showing the structure of the magnetism sensor.

FIG. 7 is an electrical control block diagram of a controller.

FIGS. 8A to 8C are diagrammatic views for describing a method for exchanging a magnetism reaction section.

FIG. 9 is a key part diagrammatic transparent side view showing the structure of a magnetism sensor according to a second embodiment.

### DESCRIPTION OF EXEMPLARY EMBODIMENTS

Embodiments will be described below with reference to the drawings. Each member in the drawings is so drawn at a different scale on a member basis as to be large enough to be recognizable in the drawings.

### First Embodiment

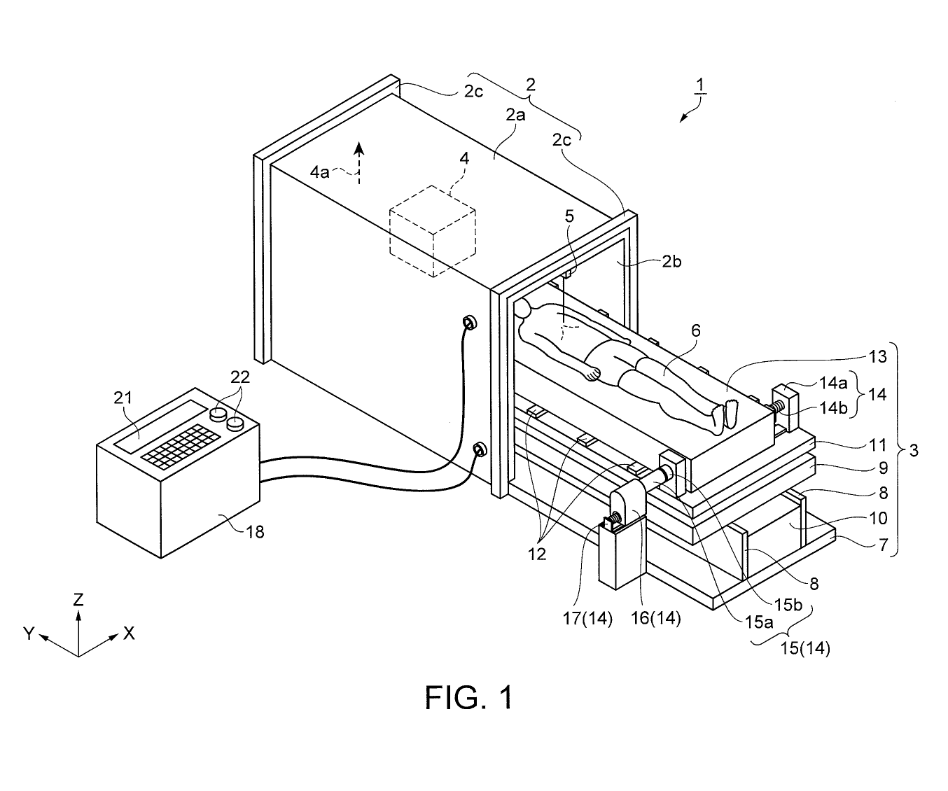

In the present embodiment, characteristic examples of a biological magnetic field measurement apparatus and a method for maintaining the biological magnetic field measurement apparatus will be described with reference to the drawings. The structure of the biological magnetic field measurement apparatus according to the present embodiment will be described with reference to FIGS. 1 to 7. FIG. 1 is a schematic perspective view showing the configuration of the biological magnetic field measurement apparatus. A biological magnetic field measurement apparatus 1 as a magnetism measurement apparatus is formed primarily of an electromagnetic shield apparatus 2, a table 3, a magnetism sensor 4 as a magnetism detection sensor, and a laser pointer 5, as shown in FIG. 1.

The electromagnetic shield apparatus 2 includes a main body section 2a having a squarely tubular shape, and the longitudinal direction of the main body section 2a is defined as a Y direction. The direction of the gravitational acceleration is defined as a −Z direction, and the direction perpendicular to the Y and Z directions is defined as an X direction. The electromagnetic shield apparatus 2 avoids a situation in which external magnetic fields, such as terrestrial magnetism, flows into the space where the magnetism sensor 4 is disposed. That is, the electromagnetic shield apparatus 2 suppresses an effect of external magnetic fields on the magnetism sensor 4 and so controls the location at which the magnetism sensor 4 is present as to be under a significantly lower intensity magnetic field than the external magnetic fields. The main body section 2a extends in the Y direction, and the main body section 2a itself functions as a passive magnetic shield. The interior of the main body section 2a forms a cavity, and a cross-sectional plane extending in the X and Z directions (XZ cross-sectional flat plane perpendicular to Y direction) has a roughly rectangular shape. In the present embodiment, the main body section 2a has a square cross-sectional shape. The electromagnetic shield apparatus 2 has a first opening 2b on the −Y-direction side, and the table 3 protrudes through the first opening 2b. The electromagnetic shield apparatus 2 does not necessarily has a specific size. In the present embodiment, for example, the Y-direction length of the electromagnetic shield apparatus 2 is about 200 cm, and one side of the first opening 2b is about 90 cm. A subject 6 laid on the table 3 can go in and go out, along with the table 3, through the first opening 2b of the electromagnetic shield apparatus 2.

The main body section 2a is made of a ferromagnetic material having a relative permeability of, for example, at least several thousands or a conductor having high conductivity. Examples of the ferromagnetic material may include Permalloy, ferrite, or iron-, chromium-, or cobalt-based amorphous material. An example of the conductor having high conductivity may include a material having a magnetic field attenuation effect based on an eddy current effect, such as aluminum. The main body section 2a can instead be formed by alternately layering a ferromagnetic material and a conductor having high conductivity. In the present embodiment, for example, the main body section 2a is formed by alternately layering an aluminum plate and a Permalloy plate, two layers in total for each of the materials, to a total thickness ranging from about 20 to 30 mm.

First Helmholtz coils 2c are provided at the +Y-direction-side end and the −Y-direction-side end of the main body section 2a. The first Helmholtz coils 2c are called first correction coils. Each of the first Helmholtz coils 2c is a coil for correcting a flow-in magnetic field that flows into the internal space of the main body section 2a. The flow-in magnetic field is an external magnetic field that passes through the first opening 2b and enters the internal space. The flow-in magnetic field is maximized in the Y direction with respect to the first opening 2b. The first Helmholtz coils 2c use current to produce a magnetic field that cancels out the flow-in magnetic field.

The table 3 includes a base 7. A pair of Y-direction rails 8, which extend in the Y direction, are provided on the base 7 of the table 3. A Y-direction table 9, which moves in the Y direction along the Y-direction rails 8, is provided on the Y-direction rails 8. A Y-direction linear motion mechanism 10, which moves the Y-direction table 9, is provided between the two Y-direction rails 8.

A Z-direction table 11 is provided on the Y-direction table 9, and a lifting/lowering apparatus that is not shown is provided between the Y-direction table 9 and the Z-direction table 11. The lifting/lowering apparatus lifts and lowers the Z-direction table 11. Six X-direction rails 12, which extend in the X direction, are provided on the +Z-direction-side surface of the Z-direction table 11. An X-direction table 13, which moves in the X direction along the X-direction rails 12, is provided on the X-direction rails 12.

An X-direction linear motion mechanism 14, which moves the X-direction table 13 in the X direction, is provided on the Z-direction table 11 and on the −Y-direction side thereof. The X-direction linear motion mechanism 14 has a pair of bearings 14a, which are so disposed as to stand on the Z-direction table 11. The X-direction table 13 is positioned between the two bearings 14a. The two bearings 14a support a first threaded rod 14b in a rotatable manner. The X-direction table 13 is provided with a first through hole that is not shown but passes through the X-direction table 13 in the X direction, and the first threaded rod 14b is so provided as to pass through the first through hole in the X-direction table 13. A female thread that is not shown is formed on the first through hole, and the first threaded rod 14b engages with the female thread.

An attachment/detachment section 15 is provided at the −X-direction-side end of the first threaded rod 14b and fixed thereto. When the attachment/detachment section 15 is rotated, the first threaded rod 14b rotates. Since the first threaded rod 14b engages with the female thread in the X-direction table 13, the X-direction table 13 moves in the X direction when the first threaded rod 14b rotates. The attachment/detachment section 15 is connected to the rotating shaft of an X-direction table motor 16. Therefore, the X-direction table motor 16 rotates the attachment/detachment section 15 to allow the X-direction table 13 to move in the X direction.

The X-direction table motor 16 is connected to a motor mover 17, which moves the X-direction table motor 16 in the X direction. When the motor mover 17 moves the X-direction table motor 16 in the −X direction, the attachment/detachment section 15 is separated into a grooved cylinder 15a and a grooved rod 15b. The grooved cylinder 15a is connected to the rotating shaft of the X-direction table motor 16, and the grooved rod 15b is connected to the first threaded rod 14b. When the attachment/detachment section 15 is separated into the grooved cylinder 15a and the grooved rod 15b, the X-direction table 13 is separate from the X-direction table motor 16 and can move in the Y direction. The X-direction linear motion mechanism 14 is formed of the bearings 14a, the first threaded rod 14b, the attachment/detachment section 15, the X-direction table motor 16, the motor mover 17, and other components.

The laser pointer 5 is provided on the +Z-direction side of the first opening 2b of the electromagnetic shield apparatus 2. The laser pointer 5 is used to position the subject 6. The subject 6 laid on the table 3 passes through the first opening 2b. Since the subject 6 passes through an area in the vicinity of the laser pointer 5, the laser pointer 5 can readily irradiate the subject 6 with a light ray.

The magnetism sensor 4 is disposed in the electromagnetic shield apparatus 2. The magnetism sensor 4 is a sensor that detects a magnetic field emitted from the heart of the subject 6. The magnetism sensor 4 is fixed to the electromagnetic shield apparatus 2. The location where the biological magnetic field measurement apparatus 1 is installed is so adjusted by the electromagnetic shield apparatus 2 as to be substantially free of magnetic field. The magnetism sensor 4 can therefore measure a magnetic field emitted from the heart without being affected by noise. The magnetism sensor 4 detects the intensity component of the magnetic field in a magnetic field detection direction 4a, which coincides with the Z direction.

The magnetic field detection direction 4a and the Y direction are perpendicular to each other. The magnetic field detection direction 4a and the X direction are perpendicular to each other. The Y direction and the X direction are also perpendicular to each other. The table 3 moves the subject 6 in the Y and X directions perpendicular to each other. Therefore, since the table 3 can be moved along an orthogonal coordinate system, the position to which the table 3 is moved can be readily controlled. The direction in which the electromagnetic shield apparatus 2 extends is the Y direction.

A controller 18 is provided at a location remote from the first opening 2b. The controller 18 causes an electric signal to flow to control the biological magnetic field measurement apparatus 1. In detail, the controller 18 controls the electromagnetic shield apparatus 2, the table 3, the magnetism sensor 4, and the laser pointer 5. The electric signal from the controller 18 produces a magnetic field and a residual magnetic field, which form noise when they are detected with the magnetism sensor 4. Since the controller 18 is positioned at a location remote from the first opening 2b, the magnetic field and the residual magnetic field produced by the controller 18 are unlikely to reach the magnetism sensor 4. As a result, the magnetism sensor 4 can perform measurement containing a small amount of noise.

The controller 18 is provided with a display apparatus 21, which serves as a display section, and an input apparatus 22. The display apparatus 21 is an LCD (liquid crystal display), an OLED (organic light-emitting diode), or any other display apparatus. The display apparatus 21 displays the situation of measurement, a result of measurement, and other types of information. The input apparatus 22 is formed, for example, of a keyboard, rotary knobs, and other components. An operator operates the input apparatus 22 to input a variety of instructions, such as an instruction to cause the biological magnetic field measurement apparatus 1 to start measurement and conditions under which the biological magnetic field measurement apparatus 1 performs measurement.

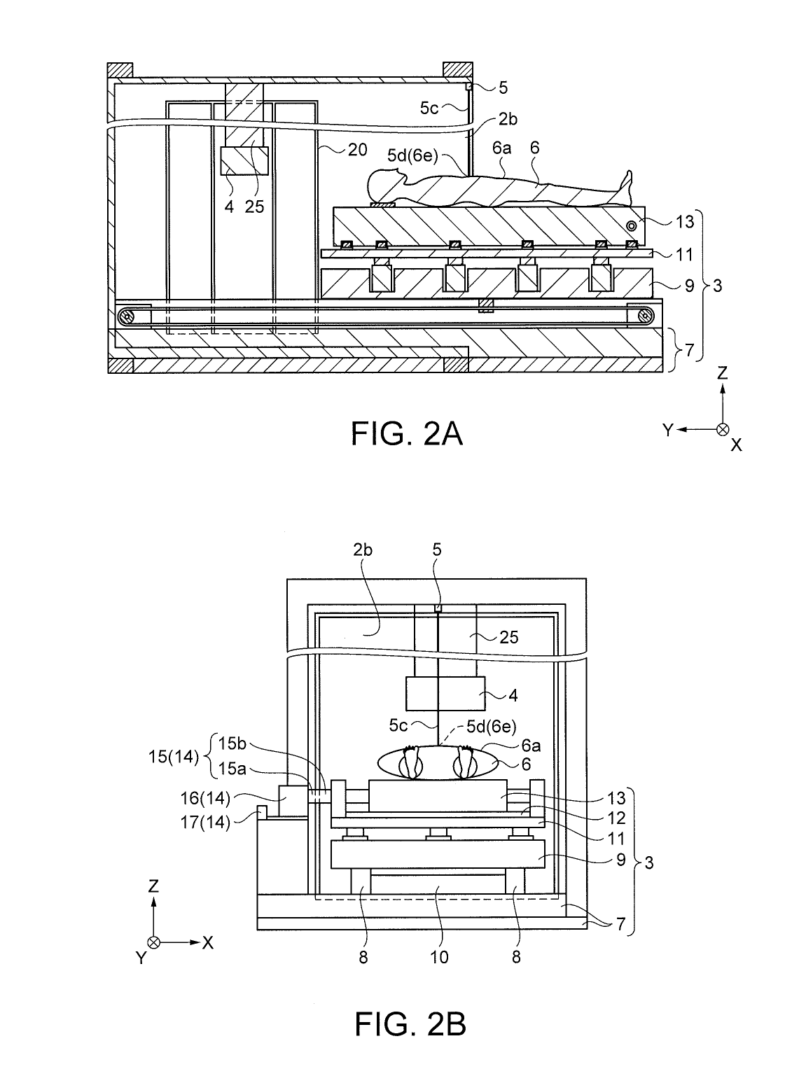

FIG. 2A is a diagrammatic side cross-sectional view for describing the structure of the biological magnetic field measurement apparatus and taken along a side surface of the electromagnetic shield apparatus 2. FIG. 2B is a diagrammatic side view for describing the structure of the biological magnetic field measurement apparatus and showing the biological magnetic field measurement apparatus 1 viewed in the −Y direction. In FIGS. 2A and 2B, the laser pointer 5 is disposed on the ceiling of the main body section 2a in the position of the first opening 2b and outputs a laser beam 5c in the −Z direction. A front surface 6a of the subject 6 is irradiated with the laser beam 5c. A reflection point 5d, where the laser beam 5c is reflected off the front surface 6a, is a single point.

To position the subject 6, the subject 6 is laid on the table 3 on his/her back. The laser pointer 5 then irradiates the chest of the subject 6 with the laser beam 5c. The positions of the Y-direction table 9 and the X-direction table 13 are so adjusted that a xiphoid process 6e positioned on the chest is irradiated with the laser beam 5c.

The operator first drives the Y-direction linear motion mechanism 10 to move the Y-direction table 9. The Y-direction table 9 is then moved to a position where the grooved cylinder 15a and the grooved rod 15b face each other. The operator then drives the motor mover 17 to cause the grooved cylinder 15a and the grooved rod 15b to link with each other. The operator further drives the X-direction linear motion mechanism 14 and the X-direction table motor 16 to move the X-direction table 13 in the X direction. The position of the X-direction table 13 is so adjusted that the laser beam 5c is located in a Y-direction line passing through the xiphoid process 6e of the subject 6. The operator then drives the motor mover 17 to separate the grooved cylinder 15a and the grooved rod 15b from each other. The operator subsequently drives the Y-direction linear motion mechanism 10 to move the Y-direction table 9 in the Y direction. The operator then adjusts the positions of the table 3 in the X and Y directions in such a way that the xiphoid process 6e is irradiated with the laser beam 5c.

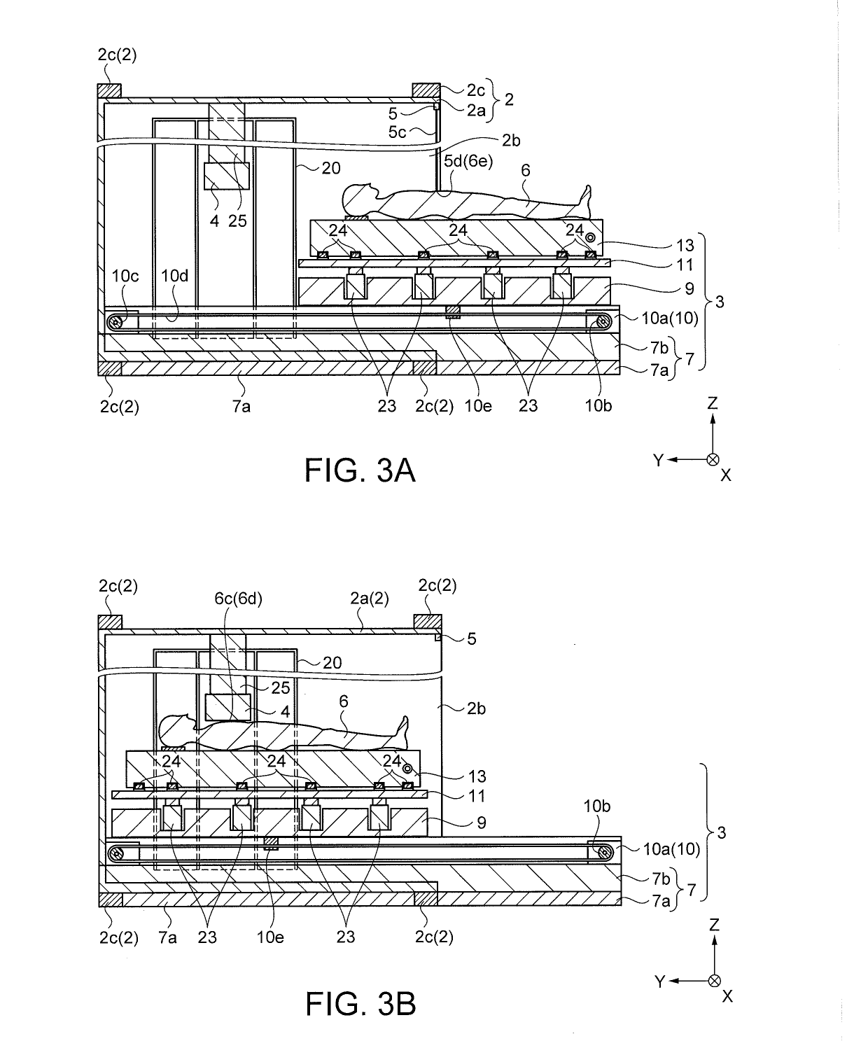

FIGS. 3A and 3B are side diagrammatic cross-sectional views showing the structure of the table. FIG. 3A shows a state in which the table 3 is moving in the −Y direction, and FIG. 3B shows a state in which the table 3 has moved into the electromagnetic shield apparatus 2 and a cardiac magnetic field from the subject 6 is being measured. The base 7 is formed of a lower base 7a and an upper base 7b, as shown in FIG. 3A. The lower base 7a is provided with the pair of first Helmholtz coils 2c. Each of the first Helmholtz coils 2c has a frame-like shape and surrounds the main body section 2a. The main body section 2a is disposed on the lower base 7a, and the upper base 7b is disposed on a −Z-direction-side portion of the main body section 2a and on the lower base 7a. A structure in which the lower base 7a and the upper base 7b sandwich part of the main body section 2a is employed. The upper base 7b is disposed on the inner bottom surface of the main body section 2a and extends from the interior of the main body section 2a through and beyond the first opening 2b along the Y direction, which is the direction in which the subject 6 is movable.

The lower base 7a and the upper base 7b only need to be made of a nonmagnetic, rigid material and are not necessarily made of a specific material. The lower base 7a and the upper base 7b are made of wood, a resin, a ceramic material, a nonmagnetic metal, or any other nonmagnetic material. In the present embodiment, the lower base 7a and the upper base 7b are made, for example, of wood. Second Helmholtz coils 20 are disposed on the upper base 7b. The Y-direction rails 8 and the Y-direction linear motion mechanism 10 are disposed above lower portions of the second Helmholtz coils 20.

The Y-direction linear motion mechanism 10 includes a motor 10a. A first pulley 10b is attached to the rotating shaft of the motor 10a, and a second pulley 10c is rotatably provided at the Y-direction-side end of the Y-direction linear motion mechanism 10. A timing belt 10d is installed between the first pulley 10b and the second pulley 10c. The timing belt 10d is provided with a linkage section 10e, which links the timing belt 10d with the Y-direction table 9. When the motor 10a rotates the first pulley 10b, the torque produced by the motor 10a moves the linkage section 10e in the Y direction. The movement of the linkage section 10e moves the Y-direction table 9. The motor 10a can therefore move the Y-direction table 9 in the Y direction. The motor 10a can change the direction in which the first pulley 10b rotates to move the Y-direction table 9 in both the +Y direction and the −Y direction.

Each of the Y-direction rails 8, the second pulley 10c, the timing belt 10d, and the linkage section 10e is made of a nonmagnetic material. The timing belt 10d is made of a rubber or resin material. Each of the Y-direction rails 8, the second pulley 10c, and the linkage section 10e is made of a ceramic material. Therefore, among the components that form the Y-direction linear motion mechanism 10, those inside the electromagnetic shield apparatus 2 are made of nonmagnetic materials.

In the Y-direction table 9, four lifting/lowering apparatus 23 are arranged in the Y direction. Each of the lifting/lowering apparatus 23 has a structure in which three air cylinders are arranged in the X direction. The lifting/lowering apparatus 23, in each of which the air cylinders are caused to extend or retract, can lift and lower the Z-direction table 11 in the magnetic field detection direction 4a. Each of the air cylinders is provided with a length measurement device that is not shown, and the lifting/lowering apparatus 23 can detect the travel of the Z-direction table 11. The lifting/lowering apparatus 23 can translate the Z-direction table 11 by causing the air cylinders to move the Z-direction table 11 by the same distance. The controller 18 accommodates a compressor, an electromagnetic valve, and other pneumatic devices that are not shown. The lifting/lowering apparatus 23 are controlled by the controller 18. Each of the Y-direction table 9, the lifting/lowering apparatus 23, and the Z-direction table 11 is made of a nonmagnetic material, for example, a ceramic material in the present embodiment. The Y-direction table 9, the lifting/lowering apparatus 23, and the Z-direction table 11 are therefore nonmagnetic.

The X-direction table 13 is provided with wheels 24, which are in contact with the X-direction rails 12. The wheels 24 rotate and allow the X-direction table 13 to readily move in the X direction. Each of the X-direction table 13, the X-direction rails 12, and the wheels 24 is made of a ceramic material, which is a nonmagnetic material. The X-direction table 13, the X-direction rails 12, and the wheels 24 are therefore nonmagnetic. Among the components that form the table 3, those that move into the electromagnetic shield apparatus 2 are nonmagnetic. A situation in which the table 3 is magnetized and affects the magnetic field measurement can therefore be avoided.

The magnetism sensor 4 is disposed on the ceiling of the main body section 2a via a support member 25. The Z-direction position of the center of the magnetism sensor 4 is at the middle of the distance between the ceiling of the main body section 2a and the bottom surface of the main body section 2a. The X-direction position of the center of the magnetism sensor 4 is at the middle of the distance between the +X-direction-side wall of the main body section 2a and the −X-direction-side wall thereof. In the Y direction, the distance between the center of the magnetism sensor 4 and the −Y-direction-side end of the main body section 2a is twice the distance between the center of the magnetism sensor 4 and a +Y-direction-side wall of the main body section 2a. When the center of the magnetism sensor 4 is thus positioned, the magnetism sensor 4 is unlikely to be affected by an external magnetic field flowing into the electromagnetic shield apparatus 2.

Each of the second Helmholtz coils 20 is disposed in the electromagnetic shield apparatus 2 and has a box-like, frame-shaped external shape. The second Helmholtz coils 20 are referred to as second correction coils. Specifically, at least 3 pairs of second correction coils are so provided as to be perpendicular to the X, Y, and Z directions, respectively. The second Helmholtz coils 20 perpendicular to the X direction, which are formed of a pair of coils, sandwich a measurement space in which the subject 6 is laid at the time of measurement and the magnetism sensor 4 in the X direction (rightward/leftward direction). The second Helmholtz coils 20 perpendicular to the X direction produce a magnetic field in the X direction in such a way that the X component of a magnetic field in each of the measurement space and the space where the magnetism sensor 4 is disposed is small enough not to adversely affect the measurement, and an external magnetic field in the X direction can thus be canceled out. The second Helmholtz coils 20 perpendicular to the Y direction, which are formed of two pairs of coils (that is, four coils), sandwich the measurement space and the magnetism sensor 4 in the Y direction (frontward/rearward direction). The second Helmholtz coils 20 perpendicular to the Y direction produce a magnetic field in the Y direction in such a way that the Y component of a magnetic field in each of the measurement space and the space where the magnetism sensor 4 is disposed is small enough not to adversely affect the measurement, and an external magnetic field in the Y direction can thus be canceled out. Since the main body section 2a has a tubular shape extending in the frontward/rearward direction, and a flow-in magnetic field along the Y direction has large intensity, the second Helmholtz coils 20 provided in the Y direction are formed of two pairs of coils. The second Helmholtz coils 20 perpendicular to the Z direction, which are formed of a pair of coils, sandwich the measurement space and the magnetism sensor 4 in the Z direction (upward/downward direction). The second Helmholtz coils 20 perpendicular to the Z direction produce a magnetic field in the Z direction in such a way that the Z component of a magnetic field in each of the measurement space and the space where the magnetism sensor 4 is disposed is small enough not to adversely affect the measurement, and an external magnetic field in the Z direction can thus be canceled out. Each of the second Helmholtz coils 20 has a square-frame shape when viewed in the direction perpendicular to the coil and is so disposed that the position of the center of the square frame coincides with the position of the center of the magnetism sensor 4. Each side of the square does not necessarily have a specific length, and the length of each side is, for example, greater than or equal to 75 cm but smaller than or equal to 85 cm in the present embodiment. Each of the second Helmholtz coils 20 in FIGS. 3A and 3B has an oblong shape for ease of illustration but actually has a square shape.

The second Helmholtz coils 20 having a square-frame shape and perpendicular to the Y direction are formed of four coils and arranged in the Y direction at equal intervals. Each of the second Helmholtz coils 20 perpendicular to the X direction, when viewed in the X direction, has a square-frame-shaped outer circumference and has a structure in which two coils are disposed in the square frame shape. Each of the second Helmholtz coils 20 is so disposed that the position of the center of the square frame coincides with the position of the center of the magnetism sensor 4.

The shape of each of the second Helmholtz coils 20 perpendicular to the Z direction, when viewed in the Z direction, is the same as the shape of each of the second Helmholtz coils 20 perpendicular to the X direction, when viewed in the X direction. Each of the second Helmholtz coils 20 perpendicular to the Z direction is so disposed that the position of the center of the square frame coincides with the position of the center of the magnetism sensor 4. Shaping the second Helmholtz coils 20 as described above allows a further decrease in a magnetic field due to external disturbance that affects the magnetism sensor 4. In particular, an effect of a magnetic field propagating from the −Y-direction side of the electromagnetic shield apparatus 2 can be lowered.

When the table 3 is positioned on the −Y-direction side, one half or more than half of the table 3 protrudes from the electromagnetic shield apparatus 2. The subject 6 can thus be readily laid on the table 3. The height from the floor to the nose of the subject 6 laid on the table 3 is lower than the height from the floor to the −Z-direction-side surface of the magnetism sensor 4. The subject 6 therefore does not interfere with the magnetism sensor 4 when the Y-direction table 9 is moved in the Y direction.

After the Y-direction table 9 is moved in the Y direction, the Z-direction table 11 is lifted, as shown in FIG. 3B. Now, let the location on the surface of a chest section 6c of the subject 6 under the measurement with the magnetism sensor 4 be a measurement surface 6d. At this point, the measurement surface 6d is so positioned as to face the magnetism sensor 4 and approaches the magnetism sensor 4. The distance between the measurement surface 6d and the magnetism sensor 4 is so set as to be short enough not to come into contact with each other. The distance is not limited to a specific value, and the distance between the measurement surface 6d and the magnetism sensor 4 is set, for example, at 5 mm in the present embodiment. The magnetism sensor 4 then measures the measurement surface 6d.

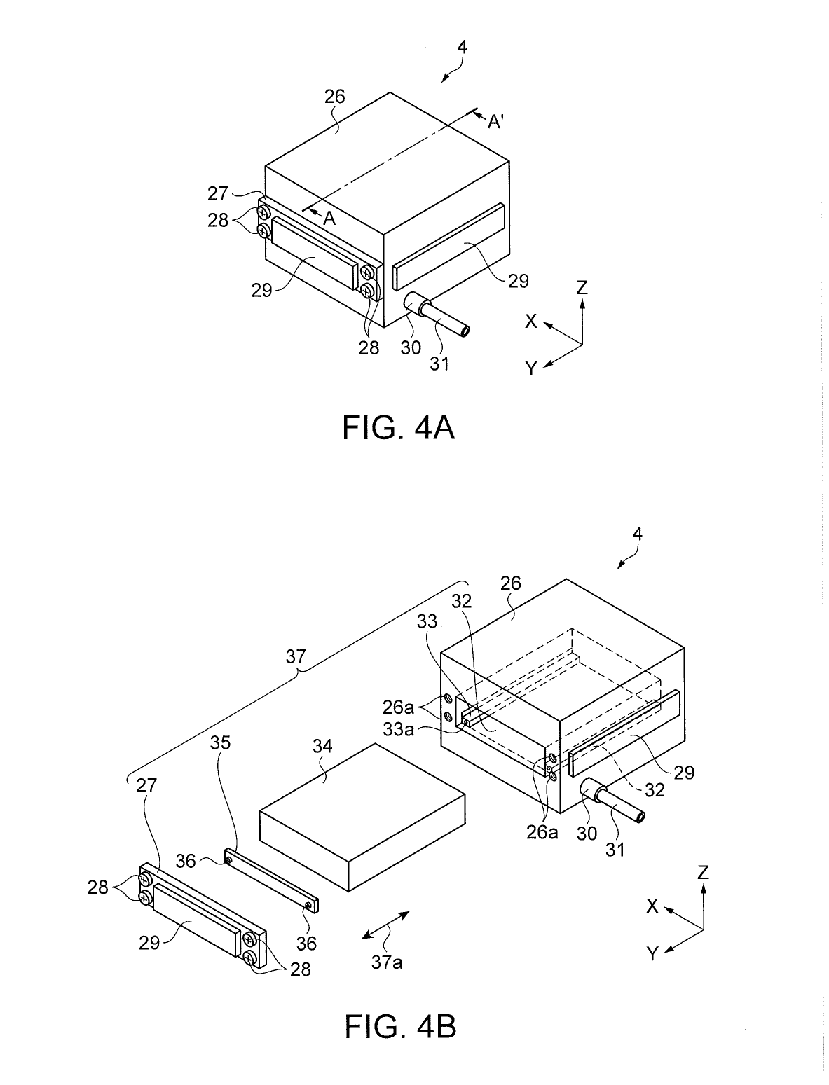

FIG. 4A is a schematic perspective view showing the structure of the magnetism sensor, and FIG. 4B is a schematic exploded perspective view showing the structure of the magnetism sensor. The magnetism sensor 4 includes a box-shaped case 26, as shown in FIG. 4A. The +Z-direction-side surface of the case 26 is a surface connected to the support member 25. A first lid 27 is provided on the +Y-direction side of the case 26. The first lid 27 is a plate elongated in the X direction. First screws 28 are disposed at the four corners of the first lid 27, and the first lid 27 is fixed to the case 26 with the first screws 28.

A heater 29 is provided on the +Y-direction-side surface of the first lid 27. The heater 29 is also provided on the −Y-direction-side surface, the +X-direction-side surface, and the −X-direction-side surface of the case 26. Each of the heaters 29 preferably has a structure that produces no magnetic field and can, for example, be a heater so configured that steam or hot air flows through a channel for heat generation. Each of the heaters 29 may instead use high-frequency voltage to heat each gas cell 53 as a gas chamber on the basis of dielectric heating.

An optical connector 30 is provided on the −X-direction-side surface of the case 26, and one end of an optical fiber 31 is connected to the optical connector 30. The other end of the optical fiber 31 is connected to the controller 18. The optical connector 30 can be attached and detached to and from the magnetism sensor 4.

The case 26 is provided with first female threaded holes 26a, as shown in FIG. 4B. The first screws 28 can be so rotated as to disengage from the first female threaded holes 26a. The first lid 27 can then be separate from the case 26. The case 26 is provide with a cavity 32, which opens in the +Y direction. The cavity 32 has a box-like shape. Rails 33 as a guide are provided on the −Z-direction side surface of the cavity 32 on the −X-direction-side and +X-direction side. The rails 33 extend in the Y direction.

A magnetism reaction section 34 is disposed on the rails 33 and movable along the rails 33. Further, the magnetism reaction section 34 can be pulled and taken out of the cavity 32. The magnetism reaction section 34 can therefore be attached and detached to and from the magnetism sensor 4. The magnetism reaction section 34 is a portion that so reacts with magnetism as to change the angle of the plane of polarization of light passing through the magnetism reaction section 34.

Female threaded holes 33a are provided through the +Y-direction-side surfaces of the rails 33. A pressing section 35 is provided on the +Y-direction side of the magnetism reaction section 34 and fixed to the rails 33 with second screws 36. The pressing section 35 can therefore be attached and detached to and from the rails 33. The cavity 32, the rails 33, the pressing section 35, the first lid 27, and other components form an accommodation section 37. In the accommodation section 37, the direction in which the magnetism reaction section 34 is moved along the rails 33 is called an attachment/detachment direction 37a. The attachment/detachment direction 37a coincides with the Y direction. The magnetism reaction section 34 can be accommodated into the accommodation section 37 and removed therefrom along the attachment/detachment direction 37a. That is, the accommodation section 37 is provided with the rails 33, which guides the magnetism reaction section 34 in the attachment/detachment direction 37a. The rails 33 can be used to readily move the magnetism reaction section 34 in the attachment/detachment direction 37a. The case 26 and the accommodation section 37 only need to be made of a nonmagnetic, rigid material, and the nonmagnetic, rigid material can, for example, be a ceramic, resin, or wood material. In the present embodiment, each of the case 26 and the accommodation section 37 are made of a ceramic material.

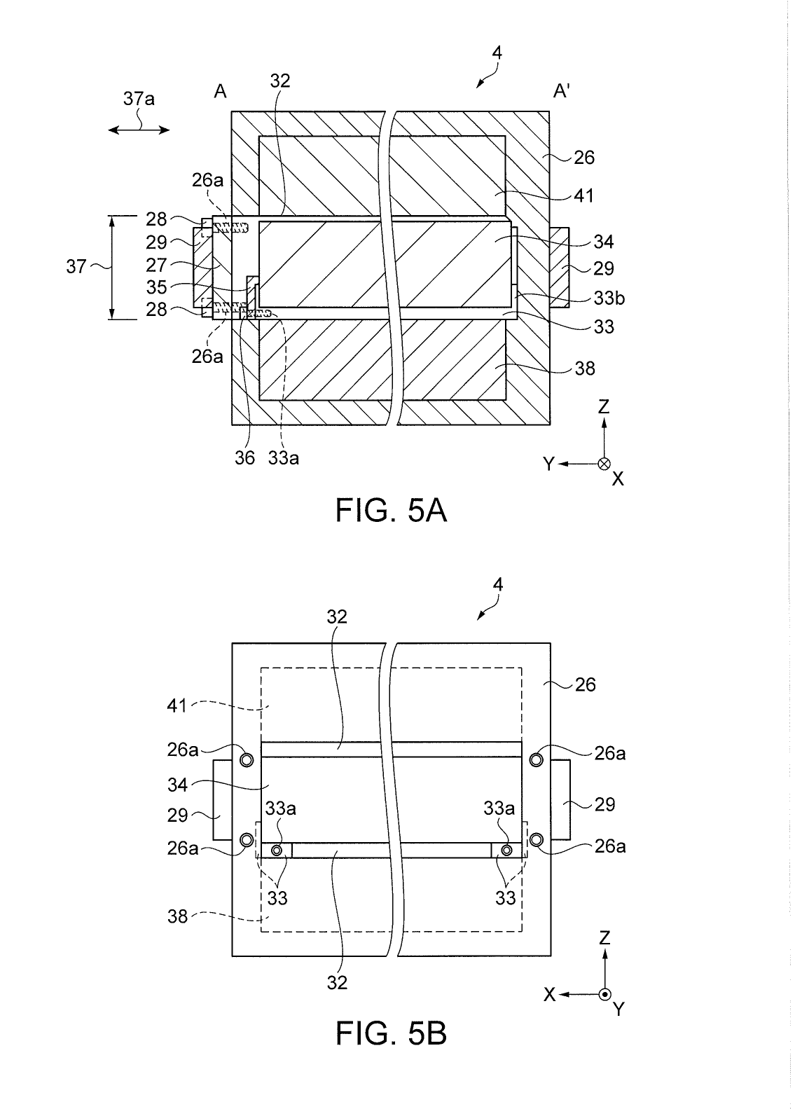

FIG. 5A is a diagrammatic side cross-sectional view showing the structure of the magnetism sensor and shows a plane cut along the line A-A′ in FIG. 4A and viewed from the −X-direction side. A light guide section 38 is provided in the case 26 and on the −Z-direction side, and a light detection section 41 is provided in the case 26 and on the +Z-direction side, as shown in FIG. 5A. The light guide section 38 is a portion that guides light to the magnetism reaction section 34, and the light detection section 41 is a portion that detects the angle of polarization of the light.

The cavity 32 is positioned between the light guide section 38 and the light detection section 41, and the rails 33 and the magnetism reaction section 34 are disposed in the cavity 32. The magnetism reaction section 34 is placed on the rails 33 by gravity. Each of the rails 33 has a protruding section 33b provided on the −Y-direction side. The pressing section 35 presses the magnetism reaction section 34 against the protruding sections 33b and fixes the magnetism reaction section 34 thereto. The Y-direction position of the magnetism reaction section 34 is thus set with good reproducibility. The first lid 27 seals the cavity 32 and prevents dirt and dust from entering the cavity 32.

FIG. 5B is a diagrammatic side view showing the structure of the magnetism sensor and shows the magnetism sensor 4 viewed from the +Y-direction side. In FIG. 5B, the first lid 27 and the pressing section 35 are omitted. The rails 33 are disposed between the light guide section 38 and the magnetism reaction section 34 and extend in the attachment/detachment direction 37a, as shown in FIG. 5B. The rails 33 are disposed on opposite sides of the magnetism reaction section 34 in the X direction perpendicular to the attachment/detachment direction 37a. Since a space is present between the pair of rails 33, light is allowed to travel from the light guide section 38 toward the magnetism reaction section 34. Further, since the magnetism reaction section 34 is supported on opposite sides in the direction perpendicular to the attachment/detachment direction 37a, the magnetism reaction section 34 can be so supported as to be separate from the light guide section 38 and the light detection section 41. As a result, the magnetism reaction section 34 and the light guide section 38 can be thermally insulated from each other, and the magnetism reaction section 34 and the light detection section 41 can be thermally insulated from each other.

The light detection section 41 is located on the +Z-direction side of the magnetism reaction section 34, and a space is present between the magnetism reaction section 34 and the light detection section 41. Light is therefore allowed to travel through the magnetism reaction section 34 toward the light detection section 41.

The rails 33 are also in contact with the +X-direction-side surface and the −X-direction-side surface of the magnetism reaction section 34. The rails 33 therefore guide the X-direction position of the magnetism reaction section 34. The rails 33 thus set the X-direction, Y-direction, and Z-direction positions of the magnetism reaction section 34 with good reproducibility.

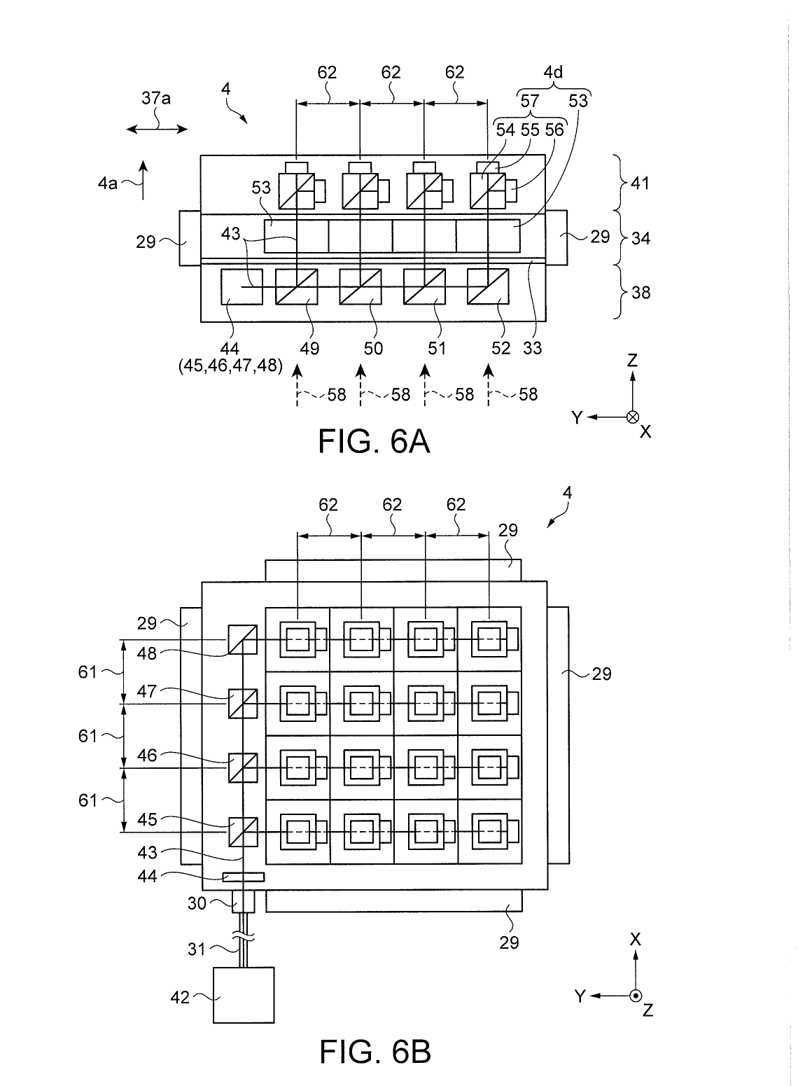

FIG. 6A is a diagrammatic transparent side view showing the structure of the magnetism sensor, and FIG. 6B is a diagrammatic plan view showing the structure of the magnetism sensor. Laser beam 43 as light from a laser light source 42 is supplied to the magnetism sensor 4, as shown in FIGS. 6A and 6B. The laser light source 42 is disposed in the controller 18, and the laser beam 43 passes through the optical fiber 31 and is supplied to the magnetism sensor 4. The magnetism sensor 4 and the optical fiber 31 are connected to each other via the optical connector 30.

The laser light source 42 outputs the laser beam 43 having a wavelength according to the absorption line of cesium. The wavelength of the laser beam 43 is not limited to a specific wavelength and is set at 894 nm, which corresponds to the D1 line, in the present embodiment. The laser light source 42 is a tunable laser, and the laser beam 43 outputted from the laser light source 42 is continuous light having a fixed amount of light.

The laser beam 43 supplied via the optical connector 30 travels to the light guide section 38. In the light guide section 38, the laser beam 43 travels in the +X direction and impinges on a polarizer 44 as a polarization conversion element. The laser beam 43 having passed through the polarizer 44 is a linearly polarized beam. The laser beam 43 then successively impinges on a first half-silvered mirror 45, a second half-silvered mirror 46, a third half-silvered mirror 47, and a first reflection mirror 48. The first half-silvered mirror 45, the second half-silvered mirror 46, and the third half-silvered mirror 47 reflect part of the laser beam 43 and cause the reflected light to travel in the −Y direction. The half-silvered mirrors transmit another part of the laser beam 43 and cause the transmitted light to travel in the +X direction. The first reflection mirror 48 reflects the entire laser beam incident thereon in the −Y direction. The first half-silvered mirror 45, the second half-silvered mirror 46, the third half-silvered mirror 47, and the first reflection mirror 48 thus separate the laser beam 43 into laser beams traveling along four optical paths. The reflectance values of the mirrors are so set that the separated laser beams 43 traveling along the optical paths have the same optical intensity.

Each of the laser beams 43 then successively impinges on a fourth half-silvered mirror 49, a fifth half-silvered mirror 50, a sixth half-silvered mirror 51, and a second reflection mirror 52. The fourth half-silvered mirror 49, the fifth half-silvered mirror 50, and the sixth half-silvered mirror 51 reflect part of the laser beam 43 and cause the reflected beams to travel in the +Z direction. The half-silvered mirrors transmit another part of the laser beam 43 and cause the transmitted beams to travel in the −Y direction. The second reflection mirror 52 reflects the entire laser beam incident thereon in the +Z direction. The fourth half-silvered mirror 49, the fifth half-silvered mirror 50, the sixth half-silvered mirror 51, and the second reflection mirror 52 thus separate the laser beam 43 traveling along the single optical path into laser beams traveling along four optical paths. The reflectance values of the mirrors are so set that the separated laser beams 43 traveling along the optical paths have the same optical intensity. The laser beam 43 is therefore separated into laser beams traveling along 16 optical paths. The reflectance values of the mirrors are so set that the separated laser beams 43 traveling along the optical paths have the same optical intensity.

The magnetism reaction section 34 is positioned on the +Z-direction side of the fourth half-silvered mirrors 49, the fifth half-silvered mirrors 50, the sixth half-silvered mirrors 51, and the second reflection mirrors 52. In the magnetism reaction section 34, the gas cells 53 are disposed on the respective optical paths of the laser beams 43. Each of the gas cells 53 is a box having a cavity provided therein, and an alkali metal gas is sealed in the cavity. The alkali metal is not limited to a specific kind and is, for example, potassium, rubidium, or cesium. The alkali metal is, for example, cesium in the present embodiment. The number of gas cells 53 is 16 in the form of four rows and four columns. The laser beams 43 reflected off the fourth half-silvered mirrors 49, the fifth half-silvered mirrors 50, the sixth half-silvered mirrors 51, and the second reflection mirrors 52 then pass through the gas cells 53.

The light detection section 41 is positioned on the +Z-direction side of the gas cells 53. The light detection section 41 is provided with polarization separators 54, each of which serves as an orthogonal separation element. Each of the polarization separators 54 is an element that separates the laser beam 43 incident thereon into two laser beams 43 having polarized light components orthogonal to each other. The polarization separator 54 can, for example, be a Wollaston prism or a polarizing beam splitter.

A first photodetector 55 is provided on the +Z-direction side of each of the polarization separators 54, and a second photodetector 56 is provide on the −Y-direction side of each of the polarization separators 54. The polarization separator 54, the first photodetector 55, and the second photodetector 56 form a light reception device 57. The first photodetector 55 is irradiated with the laser beam 43 having passed through the polarization separator 54, and the second photodetector 56 is irradiated with the laser beam 43 reflected off the polarization separator 54. Each of the first photodetector 55 and the second photodetector 56 outputs current according to the amount of the laser beam 43 incident on the photodetector to the controller 18. Since any magnetic field produced by the first photodetector 55 and the second photodetector 56 possibly affects the measurement, the first photodetector 55 and the second photodetector 56 are desirably made of a nonmagnetic material.

The magnetism sensor 4 is disposed on the +Z side of the subject 6. A magnetic vector 58 produced as magnetism by the subject 6 is inputted to the magnetism sensor 4 from the −Z-direction side. The magnetic vector 58 passes through the light guide section 38 and then passes through the gas cells 53 in the magnetism reaction section 34. The magnetic vector 58 then passes through the light detection section 41 and exits out of the magnetism sensor 4.

The magnetism sensor 4 is a sensor referred to as an optical pumping magnetometer or an optical pumping atomic magnetism sensor. In each of the gas cells 53, cesium, which is an alkali metal, is heated into gaseous cesium. When the cesium gas is irradiated with the linearly polarized laser beam 43, the cesium atoms are excited, and the orientations of the magnetic moment thereof are aligned with one another. When the magnetic vector 58 passes through the gas cells 53 in this state, the magnetic moment of the cesium atoms experiences precession due to the magnetic field of the magnetic vector 58. The precession is referred to as Larmor precession. The magnitude of Larmor precession positively correlates with the magnitude of the magnetic vector 58. Larmor precession rotates the plane of polarization of the laser beam 43. The magnitude of Larmor precession positively correlates with the amount of change in the angle of rotation of the plane of polarization of the laser beam 43. The magnitude of the magnetic vector 58 therefore positively correlates with the amount of change in the angle of rotation of the plane of polarization of the laser beam 43. The magnetism sensor 4 is highly sensitive to the magnetic vector 58 in the magnetic field detection direction 4a and is less sensitive to the component of the magnetic vector 58 that is oriented in the direction perpendicular to the magnetic field detection direction 4a.

The polarization separator 54 separates the laser beam 43 into two linearly polarized beams having components perpendicular to each other. The first photodetector 55 and the second photodetector 56 then detect the intensities of the two linearly polarized beams having components perpendicular to each other. The first photodetector 55 and the second photodetector 56 can therefore detect the angle of rotation of the plane of polarization of the laser beam 43. The magnetism sensor 4 then detects the intensity of the magnetic vector 58 from a change in the angle of rotation of the plane of polarization of the laser beam 43.

The light guide section 38 includes the polarizer 44, which outputs a linearly polarized beam. The light guide section 38 therefore outputs a linearly polarized beam to the magnetism reaction section 34. The magnetism reaction section 34 is filled with cesium gas. The magnetism reaction section 34 can therefore rotate the plane of polarization of light passing therethrough in correspondence with the intensity of magnetism. The light detection section 41, which includes the polarization separators 54, can separate each of the laser beams 43 into two linearly polarized beams polarized in directions perpendicular to each other. Detection of the optical intensities of the two linearly polarized beams allows detection of the angle of rotation of the plane of polarization. Since the angle of rotation of the plane of polarization corresponds to the intensity of the magnetism, the magnetism sensor 4 can detect the intensity of the magnetism.

A device formed of the gas cell 53, the polarization separator 54, the first photodetector 55, and the second photodetector 56 is referred to as a sensor device 4d. The magnetism sensor 4 is provided with 16 sensor devices 4d in the form of 4 rows and 4 columns. The number and arrangement of the sensor devices 4d in the magnetism sensor 4 are not limited to a specific value or a specific arrangement, and the sensor devices 4d may be arranged in the form of 3 or fewer rows or five or greater rows. Similarly, the sensor devices 4d may be arranged in the form of 3 or fewer columns or five or greater columns. The greater the number of sensor devices 4d, the higher the spatial resolution.

Now, let the interval between the sensor devices 4d in the X direction be a first device interval 61 and the interval between the sensor devices 4d in the Y direction be a second device interval 62. In the X direction, the devices are arranged at the same first device intervals 61, and in the Y direction, the devices are arranged at the same second device intervals 62. In the magnetism reaction section 34, the interval between adjacent gas cells 53 in the X direction is the first device interval 61, and the interval between adjacent gas cells 53 in the Y direction is the second device interval 62. In the light detection section 41, the interval between adjacent light reception devices 57 in the X direction is the first device interval 61, and the interval between adjacent light reception devices 57 in the Y direction is the second device interval 62. The gas cells 53 and the light reception devices 57 are therefore arranged at the same intervals. As a result, the laser beams 43 having passed through the gas cells 53 can be inputted to the respective light reception device 57.

The first half-silvered mirror 45 to the second reflection mirror 52 and the light reception devices 57 are so arranged that the optical axes of the laser beams 43 traveling from the light guide section 38 to the magnetism reaction section 34 coincide with the optical axes of the laser beams 43 traveling from the magnetism reaction section 34 to the light detection section 41 along the same straight lines. The light traveling from the light guide section 38 to the magnetism reaction section 34 can therefore be reliably inputted to the light detection section 41.

The attachment/detachment direction 37a is perpendicular to the optical axes of the laser beams 43 traveling from the light guide section 38 to the light detection section 41. The magnetism reaction section 34 can therefore be moved in the attachment/detachment direction 37a without any change in the distance between the light guide section 38 and the light detection section 41.

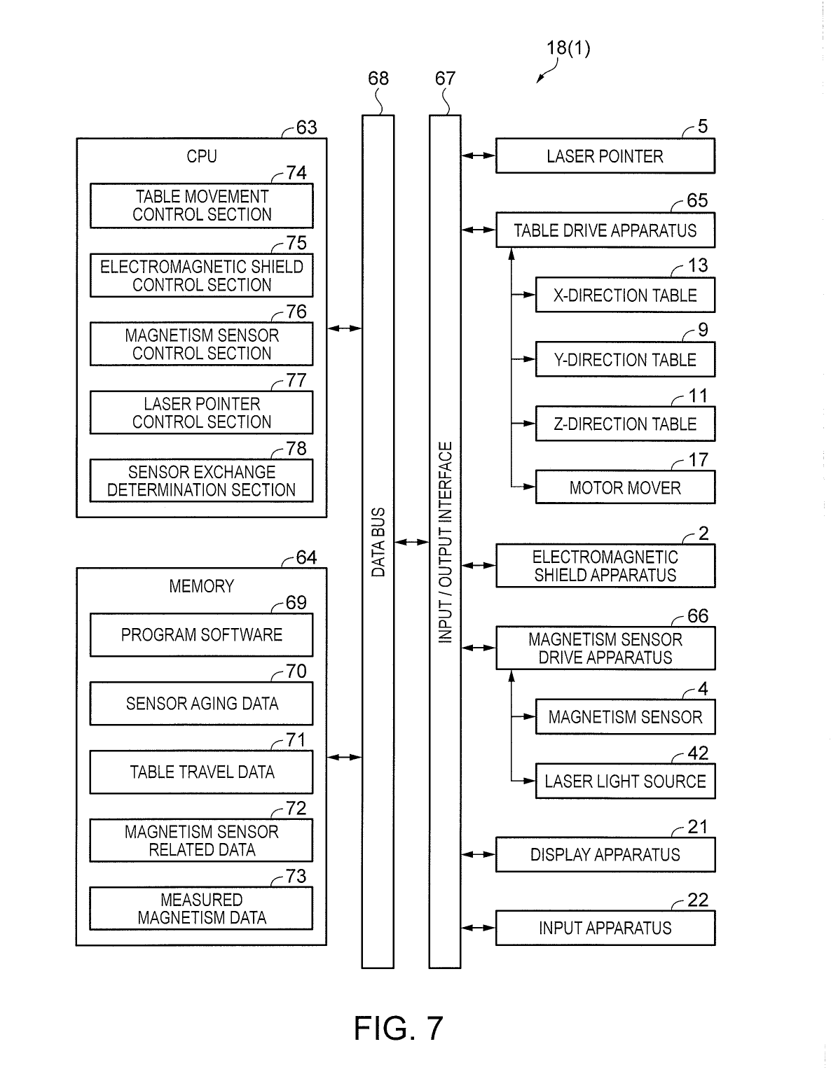

FIG. 7 is an electrical control block diagram of the controller. The biological magnetic field measurement apparatus 1 includes the controller 18, which controls the action of the biological magnetic field measurement apparatus 1, as shown in FIG. 7. The controller 18 includes a CPU 63 (central processing unit), which performs as a processor a variety of computation processes, and a memory 64, which stores a variety of types of information. The laser pointer 5, a table drive apparatus 65, the electromagnetic shield apparatus 2, a magnetism sensor drive apparatus 66, the display apparatus 21, and the input apparatus 22 are connected to the CPU 63 via an input/output interface 67 and a data bus 68.

The table drive apparatus 65 is an apparatus that drives the X-direction table 13, the Y-direction table 9, the Z-direction table 11, and the motor mover 17. The table drive apparatus 65 receives, as an input from the CPU 63, an instruction signal that instructs a shift of the position of the X-direction table 13. The X-direction table 13 is movable only when the grooved rod 15b is so positioned as to face the grooved cylinder 15a. The Y-direction table 9 is therefore first moved. The table drive apparatus 65 detects the position of the Y-direction table 9. The Y-direction table 9 is provided with a length measurement apparatus that detects the position of the Y-direction table 9 and can therefore detect the position of the Y-direction table 9. The Y-direction table 9 is then moved to a location where the grooved rod 15b faces the grooved cylinder 15a.

The table drive apparatus 65 then drives the motor mover 17 to join the grooved cylinder 15a and the grooved rod 15b with each other. The table drive apparatus 65 subsequently detects the position of the X-direction table 13. The X-direction table 13 is provided with a length measurement apparatus that detects the position of the X-direction table 13 and can therefore detect the position of the X-direction table 13. The difference between an intended position to which the X-direction table 13 is moved and the current position of the X-direction table 13 is then computed. The table drive apparatus 65 then drives the X-direction table motor 16 to move the X-direction table 13 to the intended position. The table drive apparatus 65 can thus move the X-direction table 13 to a specified location. The table drive apparatus 65 subsequently drives the motor mover 17 to separate the grooved cylinder 15a and the grooved rod 15b from each other.

Similarly, the table drive apparatus 65 receives, as an input from the CPU 63, an instruction signal that instructs a shift of the position of the Y-direction table 9. The table drive apparatus 65 detects the position of the Y-direction table 9. The difference between an intended position to which the Y-direction table 9 is moved and the current position of the Y-direction table 9 is then computed. The table drive apparatus 65 then drives the motor 10a to move the Y-direction table 9 to the intended position. The table drive apparatus 65 can thus move the Y-direction table 9 between a position in the electromagnetic shield apparatus 2 and a position outside the electromagnetic shield apparatus 2.

Similarly, the table drive apparatus 65 receives, as an input from the CPU 63, an instruction signal that instructs a shift of the position of the Z-direction table 11. Each of the lifting/lowering apparatus 23, which lifts and lowers the Z-direction table 11, is provided with a length measurement apparatus that detects the position of the Z-direction table 11, and the table drive apparatus 65 detects the position of the Z-direction table 11. The difference between an intended position to which the Z-direction table 11 is moved and the current position of the Z-direction table 11 is then computed. Each of the lifting/lowering apparatus 23 is formed of air cylinders, and the table drive apparatus 65 includes a compressor, an electromagnetic valve, and other pneumatic device that drive the lifting/lowering apparatus 23. The table drive apparatus 65 then controls the amount of air to be supplied to the lifting/lowering apparatus 23 to move the Z-direction table 11 to the intended position.

The electromagnetic shield apparatus 2 includes the first Helmholtz coils 2c, the second Helmholtz coils 20, and a sensor that detects a magnetic field inside the electromagnetic shield apparatus 2. The electromagnetic shield apparatus 2 receives an instruction from the CPU 63 and so drives the first Helmholtz coils 2c and the second Helmholtz coils 20 as to lower the magnetic field in the main body section 2a.

The magnetism sensor drive apparatus 66 is an apparatus that drives the magnetism sensor 4 and the laser light source 42. The magnetism sensor 4 is provided with the first photodetectors 55, the second photodetectors 56, and the heaters 29. The magnetism sensor drive apparatus 66 drives the laser light source 42, the heaters 29, the first photodetectors 55, and the second photodetectors 56. The magnetism sensor drive apparatus 66 drives the laser light source 42 to supply the magnetism sensor 4 with the laser beam 43. The magnetism sensor drive apparatus 66 further drives the heaters 29 to maintain the magnetism reaction section 34 in the magnetism sensor 4 at a predetermined temperature. The magnetism sensor drive apparatus 66 then converts electric signals outputted by the first photodetectors 55, the second photodetectors 56 into digital signals and outputs them to the CPU 63.

The display apparatus 21 displays predetermined information in accordance with an instruction from the CPU 63. The operator operates the input apparatus 22 on the basis of the content of the display to input the content of an instruction. The content of the instruction is transmitted to the CPU 63. The display apparatus 21 further displays the state of magnetism detected with the magnetism sensor 4. The operator looks at the display apparatus 21 to browse a result of the examination of the subject 6.

The memory 64 is a concept including semiconductor memories, such as a RAM and a ROM, and external storage devices, such as a hard disk drive and a DVD-ROM. From a functional point of view, in the memory 64 are set a storage area for storing program software 69, which describes a procedure of control of the action of the biological magnetic field measurement apparatus 1, and a storage area for storing sensor aging data 70, which is data on cumulative period for which the magnetism reaction section 34 in the magnetism sensor 4 has operated. The sensor aging data 70 is reset when the magnetism reaction section 34 is exchanged. The period for which the magnetism reaction section 34 has operated is then newly accumulated in the sensor aging data 70. Additionally, in the memory 64 is set a storage area for storing table travel data 71, which is data on the travels of the X-direction table 13, the Y-direction table 9, and the Z-direction table 11.

Still additionally, in the memory 64 is set a storage area for storing magnetism sensor related data 72, which is data, for example, on parameters used to drive the magnetism sensor 4. Still additionally, in the memory 64 is set a storage area for storing measured magnetism data 73, which is data measured with the magnetism sensor 4. Still additionally, in the memory 64 is set a storage area that functions, for example, as a work area for the CPU 63 and a temporary file, and a variety of other storage areas.

The CPU 63 follows the program software 69 stored in the memory 64 to control the measurement of a magnetic field emitted from the heart of the subject 6. The CPU 63 has a table movement control section 74 as a specific function achievement section. The table movement control section 74 is a portion that controls the movement of the X-direction table 13, the Y-direction table 9, and the Z-direction table 11 and positions where the tables stop moving. The CPU 63 further includes an electromagnetic shield control section 75. The electromagnetic shield control section 75 is a portion that drives the electromagnetic shield apparatus 2 to suppress the magnetic field around the magnetism sensor 4.

The CPU 63 further includes a magnetism sensor control section 76. The magnetism sensor control section 76 is a portion that causes the magnetism sensor drive apparatus 66 to drive the magnetism sensor 4 for detection of the magnitude of the magnetism vector 58. The CPU 63 further includes a laser pointer control section 77. The laser pointer control section 77 is a portion that drives the laser pointer 5 to allow only a single predetermined location to be irradiated with the laser beam 5c.

The CPU 63 further includes a sensor exchange determination section 78. The sensor exchange determination section 78 is a portion that compares the sensor aging data 70 with a determination value and determines that the magnetism reaction section 34 should be exchanged when the period for which the magnetism reaction section 34 has operated exceeds the determination value. Having determined that the magnetism reaction section 34 should be exchanged, the sensor exchange determination section 78 instructs the display apparatus 21 to cause it to display a message that prompts the operator to exchange the magnetism reaction section 34. In the present embodiment, the CPU 63 in conjunction with the program software is used to achieve the above functions of the biological magnetic field measurement apparatus 1. However, when a discrete electronic circuit (hardware) that does not use the CPU 63 can achieve the functions described above, the electronic circuit can instead be used.

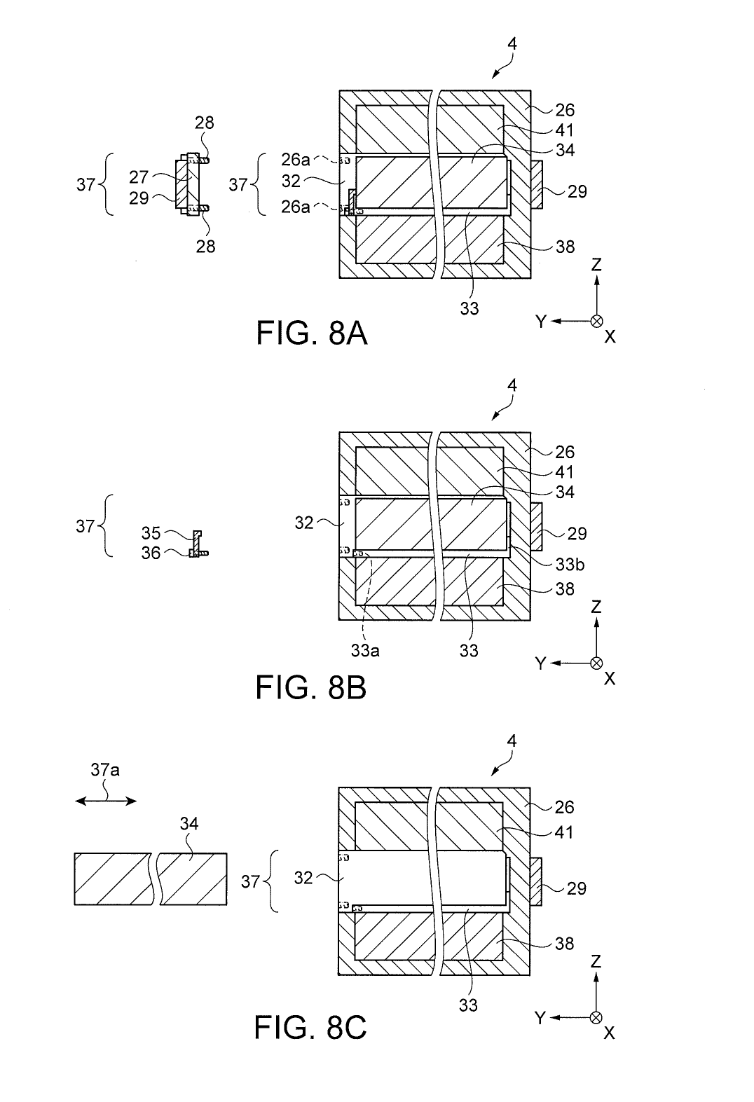

An exchange method for exchanging the magnetism reaction section 34 in the biological magnetic field measurement apparatus 1 described above will next be described with reference to FIGS. 8A to 8C. FIGS. 8A to 8C are diagrammatic views for describing the method for exchanging the magnetism reaction section.

The magnetism reaction section 34 is disposed in the case 26, as shown in FIG. 8A. The period for which the magnetism reaction section 34 has operated exceeded the determination value, and the operator exchanges the magnetism reaction section 34. The operator first rotates the four first screws 28 attached through the first lid 27. As a result, the first screws 28 are caused to disengage from the first female threaded holes 26a. The first lid 27 is then caused to be separate from the case 26. As a result, the cavity 32, the pressing section 35, the second screws 36, and part of the magnetism reaction section 34 are exposed through the +Y-direction side of the case 26.

The operator rotates the two second screws 36 attached through the pressing section 25, as shown in FIG. 8B. As a result, the second screws 36 are caused to disengage from the second female threaded holes 33a. The pressing section 35 is then caused to separate from the rails 33. As a result, the cavity 32 and the magnetism reaction section 34 are exposed through the +Y-direction side of the case 26. The magnetism reaction section 34 is placed on the rails 33.

The operator moves the magnetism reaction section 34 in the +Y direction, which is the detachment direction of the attachment/detachment direction 37a, along the rails 33, as shown in FIG. 8C. As a result, the magnetism reaction section 34 is caused to be separate from the case 26. An unused magnetism reaction section 34 is subsequently set in the cavity 32 of the case 26. The unused magnetism reaction section 34 is moved in the −Y direction, which is the attachment direction of the attachment/detachment direction 37a, along the rails 33.

The operator causes the suppressing section 35 to come into contact with the rails 33 and the magnetism reaction section 34, as shown in FIG. 8B. The operator then rotates the two second screws 36 to cause the second screws 36 to engage with the second female threaded holes 33a. As a result, the magnetism reaction section 34 is fixed to the case 26. Since the +X-direction side surfaces of the magnetism reaction section 34 are sandwiched between the rails 33, the X-direction position of the magnetism reaction section 34 is set by the rails 33. Since the +Y-direction side surfaces of the magnetism reaction section 34 are sandwiched between the protruding sections 33b of the rails 33 and the pressing section 35, the Y-direction position of the magnetism reaction section 34 is set by the rails 33 and the pressing section 35. Since the magnetism reaction section 34 is placed on the rails 33 and pressed by gravity against the rails 33, the Z-direction position of the magnetism reaction section 34 is set by the rails 33.

The operator causes the first lid 27 to come into contact with a periphery of an opening of the cavity 32 of the case 26, as shown in FIG. 8A. The operator then rotates the four first screws 28 to cause the first screws 28 to engage with the first female threaded holes 26a. As a result, the first lid 27 is fixed to the case 26. The magnetism reaction section 34 has been thus exchanged. As describe above, in the operation of exchanging the magnetism reaction section 34, the light guide section 38 and the light detection section 41 are not removed out of the case 26. Therefore, since the optical axes of the laser beams 43 from the light guide section 38 via the magnetism reaction section 34 to the light detection section 41 remain unchanged in terms of position, adjustment of the optical axes of the light guide section 38 and the light detection section 41 is not required, whereby the magnetism reaction section 34 can be exchanged with high productivity.

As described above, according to the present embodiment, the following advantageous effects are provided.

(1) According to the present embodiment, the magnetism reaction section 34 is so provided as to be attachable and detachable to and from the light guide section 38 and the light detection section 41. The cesium gas with which the gas cells 53 are filled leaks out with time in some cases. Exchange of the magnetism reaction section 34 after a predetermined period elapses allows recovery of the magnetism detection sensitivity. The light guide section 38 and the light detection section 41 are positionally fixed to each other. Therefore, even when the magnetism reaction section 34 is removed from the light guide section 38 and the light detection section 41 and then reinstalled again, the optical path from the light guide section 38 toward the light detection section 41 remains unchanged. As a result, even when the magnetism reaction section 34 is exchanged, optical path adjustment needs can be omitted, whereby the magnetism detection sensitivity can be readily recovered.

(2) According to the present embodiment, the magnetism sensor 4 includes the accommodation section 37, which accommodates the magnetism reaction section 34 in an attachable and detachable manner. The accommodation section 37 includes the cavity 32, in which the magnetism reaction section 34 is disposed. Therefore, even when the magnetism reaction section 34 is removed, the cavity 32, in which the magnetism reaction section 34 is disposed, is left. As a result, the magnetism reaction section 34 can be readily placed in a predetermined position in the magnetism sensor 4.

(3) According to the present embodiment, the magnetism reaction section 34 includes a plurality of gas cells 53. Further, the light detection section 41 includes a plurality of light reception devices 57, which receive the laser beams 43. Since the light guide section 38 guides the laser beams 43 to the magnetism reaction section 34, the laser beams 43 pass through the plurality of gas cells 53. Since the gas cells 53 and the light reception devices 57 are arranged at the same intervals, the laser beams 43 having passed through the gas cells 53 can be inputted to the respective light reception devices 57.

(4) According to the present embodiment, the optical axes of the laser beams traveling from the light guide section 38 to the magnetism reaction section 34 and the optical axes of the laser beams traveling from the magnetism reaction section 34 to the light detection section 41 coincide with each other along the same straight lines. The laser beams 43 traveling from the light guide section 38 to the magnetism reaction section 34 can be reliably inputted to the light detection section 41.

(5) According to the present embodiment, the attachment/detachment direction 37a is perpendicular to the optical axes of the laser beams traveling from the light guide section 38 to the light detection section 41. The magnetism reaction section 34 can therefore be moved in the attachment/detachment direction 37a without any change in the distance between the light guide section 38 and the light detection section 41.

(6) According to the present embodiment, the accommodation section 37 includes the rails 33, which guide the magnetism reaction section 34 in the attachment/detachment direction 37a. The magnetism reaction section 34 can therefore be readily moved in the attachment/detachment direction 37a along the rails 33.

(7) According to the present embodiment, the rails 33 are disposed on opposite sides of the magnetism reaction section 34 in the direction perpendicular to the attachment/detachment direction 37a. The rails 33 extend in the attachment/detachment direction 37a. Therefore, since the magnetism reaction section 34 is supported on opposite sides in the direction perpendicular to the attachment/detachment direction 37a, the magnetism reaction section 34 can be so supported as to be separate from the light guide section 38 and the light detection section 41. As a result, the magnetism reaction section 34 and the light guide section 38 can be thermally insulated from each other, and the magnetism reaction section 34 and the light detection section 41 can be thermally insulated from each other.

(8) According to the present embodiment, the light guide section 38, the magnetism reaction section 34, and the light detection section 41 are arranged in this order. Therefore, since the three sections are sequentially arranged in the direction in which the laser beams 43 travel, no optical element that controls the passage of the laser beams 43 is required, whereby a high-productivity structure can be achieved with a small number of elements.

(9) According to the present embodiment, the light guide section 38 includes the polarizer 44, which outputs a linearly polarized beam. The light guide section 38 therefore outputs a linearly polarized beam to the magnetism reaction section 34. The magnetism reaction section 34 is filled with a gas containing an alkali metal. The magnetism reaction section 34 can therefore rotate the plane of polarization of light passing therethrough in correspondence with the intensity of magnetism. The light detection section 41, which includes the polarization separators 54, can separate each of the laser beams 43 into two linearly polarized beams polarized in directions perpendicular to each other. Detection of the optical intensities of the two linearly polarized beams therefore allows detection of the angle of rotation of the plane of polarization. Since the angle of rotation of the plane of polarization corresponds to the intensity of the magnetism, the magnetism sensor 4 can detect the intensity of magnetism.

(10) According to the present embodiment, the biological magnetic field measurement apparatus 1 includes the magnetism sensor 4 and the display apparatus 21. The magnetism sensor 4 detects magnetism, and the display apparatus 21 displays the state of the magnetism. The magnetism sensor 4 is so configured that the magnetism reaction section 34 can be exchanged. The biological magnetic field measurement apparatus 1 can therefore be an apparatus including the magnetism sensor 4 that allows exchange of the magnetism reaction section 34 to readily recover the magnetism detection sensitivity.

### Second Embodiment

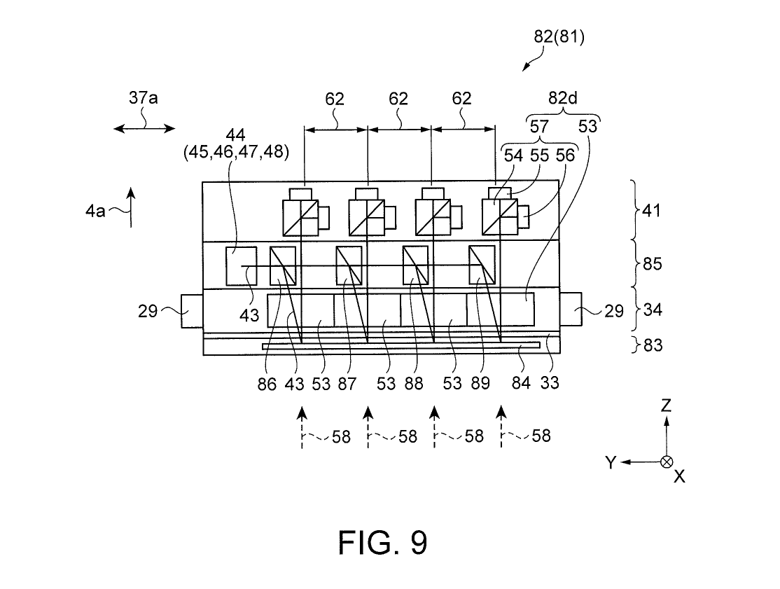

An embodiment of the magnetism sensor, which is a form in which the invention is embodied, will next be described with reference to FIG. 9, which is a key part diagrammatic transparent side view of the magnetism sensor.

The present embodiment differs from the first embodiment in that a reflection section, the magnetism reaction section 34, a light guide section, and the light detection section 41 are sequentially layered on each other. The same points as those in the first embodiment will not be described.

That is, in the present embodiment, a magnetism sensor 82, which is provided in a biological magnetic field measurement apparatus 81, includes a reflection section 83, as shown in FIG. 9. The reflection section 83 includes a reflection plate 84, which reflects the laser beams 43. The reflection plate 84 extends in the X and Y directions. The reflection plate 84 so reflects the laser beams 43 traveling from the +Z-direction side to the −Z-direction side as to cause the reflected laser beam to travel in the +Z direction.

The rails 33 are disposed on the reflection section 83, and the magnetism reaction section 34 is placed on the rails 33. The gas cells 53 are arranged in the form of 4 rows and 4 columns in the magnetism reaction section 34. The magnetism reaction section 34 is movable in the attachment/detachment direction 37a along the rails 33. The magnetism reaction section 34 is attachable and detachable to and from the magnetism sensor 82.

A light guide section 85 is provided on the +Z-direction side of the magnetism reaction section 34 with a gap therebetween. The light guide section 85 includes the polarizer 44, the first half-silvered mirror 45, the second half-silvered mirror 46, the third half-silvered mirror 47, and the first reflection mirror 48. The light guide section 85 further includes fourth half-silvered mirrors 86, fifth half-silvered mirrors 87, sixth half-silvered mirrors 88, and second reflection mirrors 89. The light detection section 41 is disposed on the +Z-direction side of the light guide section 85. The light guide section 85 and the light detection section 41 are fixed to each other. The reflection section 83 is also fixed to the light guide section 85 and the light detection section 41 via a case that is not shown. The reflection section 83, the light guide section 85, and the light detection section 41 are therefore so configured that the positions thereof relative to each other remain unchanged even when the magnetism reaction section 34 is moved. The light reception devices 57, which are disposed in the light detection section 41, and the gas cells 53 form sensor devices 82d.

The laser beam 43 supplied through the optical connector 30 travels to the light guide section 85. In the light guide section 85, the laser beam 43 travels in the +X direction and impinges on the polarizer 44. The laser beam 43 having passed through the polarizer 44 is a linearly polarized beam. The laser beam 43 sequentially impinges on the first half-silvered mirror 45, the second half-silvered mirror 46, the third half-silvered mirror 47, and the first reflection mirror 48. The first half-silvered mirror 45, the second half-silvered mirror 46, the third half-silvered mirror 47, and the first reflection mirror 48 separate the laser beam 43 into laser beams along four optical paths, and the separated laser beams travel in the −Y direction.

Each of the laser beams 43 then sequentially impinges on the corresponding fourth half-silvered mirror 86, fifth half-silvered mirror 87, sixth half-silvered mirror 88, and second reflection mirror 89. The fourth half-silvered mirror 86, the fifth half-silvered mirror 87, and the sixth half-silvered mirror 88 reflect part of the laser beam 43 and cause the reflected beam to travel in the −Z direction. The half-silvered mirrors transmit another part of the laser beam 43 and cause the transmitted beam to travel in the −Y direction. The second reflection mirror 89 reflects the entire laser beam incident thereon in the −Z direction. The fourth half-silvered mirror 86, the fifth half-silvered mirror 87, the sixth half-silvered mirror 88, and the second reflection mirror 89 thus separate the laser beam 43 traveling along the single optical path into laser beams traveling along four optical paths. The laser beam 43 is therefore separated into laser beams traveling along 16 optical paths. The reflectance values of the mirrors are so set that the separated laser beams 43 traveling along the optical paths have the same light intensity.

The magnetism reaction section 34 is positioned on the −Z-direction side of the fourth half-silvered mirrors 86, the fifth half-silvered mirrors 87, the sixth half-silvered mirrors 88, and the second reflection mirrors 89. In the magnetism reaction section 34, the gas cells 53 are disposed on the optical paths of the laser beams 43. The laser beams 43 reflected off the fourth half-silvered mirrors 86, the fifth half-silvered mirrors 87, the sixth half-silvered mirrors 88, and the second reflection mirrors 89 then pass through the gas cells 53.

The reflection section 83 is positioned on the −Z-direction side of the magnetism reaction section 34. The laser beams 43 having passed through the gas cells 53 are inputted to the reflection section 83, are reflected off the reflection plate 84, and return to the gas cells 53. Therefore, since the laser beams 43 pass through the gas cells 53 twice, the distance over which the laser beams 43 pass through the gas cells 53 is twice the distance in the case of the magnetism sensor 4 according to the first embodiment. The laser beams 43 having passed through the gas cells 53 pass through the light guide section 85 and enter the light reception devices 57 in the light detection section 41. The structure and effect of the light detection section 41 are the same as those in the first embodiment and will not be described.

As described above, according to the present embodiment, the following advantageous effect is provided.

(1) According to the present embodiment, the light guide section 85 guides the laser beams 43 to the magnetism reaction section 34. The laser beams 43 having passed through the magnetism reaction section 34 are reflected off the reflection section 83 and pass through the magnetism reaction section 34 again. The laser beams 43 having passed through the magnetism reaction section 34 pass through the light guide section 85 and enter the light detection section 41. The magnetism reaction section 34 rotates the angle of rotation of the plane of polarization of each of the laser beams 43 in accordance with the intensity of magnetism, and the light detection section 41 detects the angle of rotation of the plane of polarization. The magnetism sensor 82 can therefore detect the intensity of the magnetism. Further, since the laser beams 43 pass through the magnetism reaction section 34 twice, the amount of effect of the magnetism on the laser beams 43 is doubled. The magnetism sensor 82 can therefore detect the magnetism with high sensitivity.

The invention is not limited to the embodiments described above, and a variety of changes and modifications can be made thereto by a person skilled in the art to the extent that the changes and modifications fall within the technical spirit of the invention. Variation will be described below.

### Variation 1

In the first embodiment described above, the attachment/detachment direction 37a in the magnetism sensor 4 coincides with the Y direction, and the magnetism reaction section 34 is moved in the +Y direction for attachment and detachment thereof. The direction in which the magnetism sensor 4 is disposed on the support member 25 may be changed. The magnetism reaction section 34 may then instead be moved in the −Y direction for attachment and detachment thereof. Still instead, the attachment/detachment direction 37a may be so set as to coincide with the X direction, and the magnetism reaction section 34 may be moved in the X direction for attachment and detachment thereof. The magnetism reaction section 34 can be readily attached and detached.

### Variation 2

In the embodiments describe above, a magnetic field is measured in the electromagnetic shield apparatus 2. When the biological magnetic field measurement apparatus 1 is installed in an electromagnetically shielded room, the electromagnetic shield apparatus 2 may be omitted. In this case, the number of parts can be reduced, whereby the biological magnetic field measurement apparatus 1 can be manufactured with high productivity.

### Variation 3

In the embodiments describe above, the electromagnetic shield apparatus 2 has no −Y-direction-side wall but has an opening. A door may be provided at the location where the electromagnetic shield apparatus 2 has the −Y-direction side opening. The door is made of the same magnetism shielding material of the main body section 2a. The door is closed when the Y-direction table 9 is accommodated in the electromagnetic shield apparatus 2. The door can shield magnetism traveling from the −Y-direction side of the electromagnetic shield apparatus 2 toward the magnetism sensor 4. As a result, the magnetism sensor 4 can detect a magnetic field from the subject 6 more accurately with no effect of disturbance on the magnetic field.

When a door is provided on the −Y-direction side of the electromagnetic shield apparatus 2, the positions of the magnetism sensor 4 and the second Helmholtz coils 20 are preferably changed. The Y-direction position of the center of the magnetism sensor 4 is set at the middle of the distance between the +Y-direction-side wall of the main body section 2a and the −Y-direction-side door. Further, the position of the center of each of the second Helmholtz coils 20 is so set as to coincide with the position of the center of the magnetism sensor 4. When the center of the magnetism sensor 4 is positioned as described above, the magnetism sensor 4 is unlikely to be affected by a magnetic field entering the electromagnetic shield apparatus 2 from outside.

### Variation 4

In the embodiments describe above, the heaters 29 are disposed on the case 26. The heaters 29 may instead be attached to the magnetism reaction section 34. In this case, since the heat source is closer to the gas cells 53, the gas cells 53 can be efficiently heated.

### Variation 5

In the embodiments describe above, each of the heaters 29 is so configured that steam, hot air, or high-frequency voltage is used for heat generation. Each of the heaters 29 may instead be a ceramic heater. In this case, the heating is activated when no measurement is made, whereas the heating is deactivated when measurement is made. A situation in which measurement is affected by a magnetic field can thus be avoided.

### Variation 6

In the embodiments describe above, the gas cells 53 are arranged in the magnetism reaction section 34. The magnetism reaction section 34 may instead be formed only of a plurality of gas cells 53 bonded to each other or a plurality of gas cells 53 arranged in a container. The container may be made of a material that is magnetized by a degree small enough not to affect measurement and has high thermal conductivity. Examples of the material of the container may include graphite and silicon carbide. When a container is used, the heaters 29 may be disposed in the container. The container may be provided with recesses and protrusions for positioning the heaters 29 so that the heaters 29 are disposed in the container with high positional accuracy.

The entire disclosure of Japanese Patent Application No. 2015-77457, filed Apr. 6, 2015 is expressly incorporated by reference herein.

What is claimed is:

1. A magnetism detection sensor comprising:
a magnetism reaction section having a gas chamber filled with a gas that rotates a plane of polarization of light passing through the magnetism reaction section in correspondence with intensity of magnetism;
a light guide section that guides the light to the magnetism reaction section; and
a light detection section that detects an angle of rotation of the plane of polarization of the light having passed through the magnetism reaction section,
wherein the light guide section and the light detection section are positionally fixed to each other, and the magnetism reaction section is so provided as to be attachable and detachable to and from the light guide section and the light detection section.

2. The magnetism detection sensor according to claim 1, further comprising
an accommodation section that accommodates the magnetism reaction section in an attachable and detachable manner.

3. The magnetism detection sensor according to claim 1,
wherein the gas chamber in the magnetism reaction section is formed of a plurality of gas chambers,
the light detection section includes a plurality of light reception devices that receive the light,
the light guide section guides the light to the plurality of gas chambers, and
the gas chambers and the light reception devices are arranged at the same intervals.

4. The magnetism detection sensor according to claim 1,
wherein the light guide section and the light detection section are so disposed that an optical axis of the light traveling from the light guide section to the magnetism reaction section and an optical axis of the light traveling from the magnetism reaction section to the light detection section coincide with each other along the same straight line.

5. The magnetism detection sensor according to claim 4,
wherein an attachment/detachment direction in which the magnetism reaction section is moved when the magnetism reaction section is attached or detached is perpendicular to the optical axis of the light traveling from the light guide section to the light detection section.

6. The magnetism detection sensor according to claim 5,
wherein the accommodation section includes a guide section that guides the magnetism reaction section in the attachment/detachment direction.

7. The magnetism detection sensor according to claim 6,
wherein the guide section extends in the attachment/detachment direction and is formed of guide sections disposed on opposite sides of the magnetism reaction section in a direction perpendicular to the attachment/detachment direction.

8. The magnetism detection sensor according to claim 1,
wherein the magnetism reaction section is positioned between the light guide section and the light detection section.

9. The magnetism detection sensor according to claim 1, further comprising
a reflection section that so reflects the light traveling from the light guide section as to cause the reflected light to travel toward the light detection section,
wherein the reflection section, the magnetism reaction section, the light guide section, and the light detection section are arranged in this order.

10. The magnetism detection sensor according to claim 1,
wherein the light guide section includes a polarization conversion element that outputs linearly polarized light, the gas contains an alkali metal, and the light detection section includes an orthogonal separation element.

11. A magnetism measurement apparatus comprising:
a magnetism detection sensor that detects magnetism emitted from a subject; and
a display section that displays a state of the magnetism detected with the magnetism detection sensor,
wherein the magnetism detection sensor is the magnetism detection sensor according to claim 1.

12. A magnetism measurement apparatus comprising:
a magnetism detection sensor that detects magnetism emitted from a subject; and
a display section that displays a state of the magnetism detected with the magnetism detection sensor,
wherein the magnetism detection sensor is the magnetism detection sensor according to claim 2.

13. A magnetism measurement apparatus comprising:
a magnetism detection sensor that detects magnetism emitted from a subject; and
a display section that displays a state of the magnetism detected with the magnetism detection sensor,
wherein the magnetism detection sensor is the magnetism detection sensor according to claim 3.

14. A magnetism measurement apparatus comprising:
a magnetism detection sensor that detects magnetism emitted from a subject; and
a display section that displays a state of the magnetism detected with the magnetism detection sensor,
wherein the magnetism detection sensor is the magnetism detection sensor according to claim 4.

15. A magnetism measurement apparatus comprising:
a magnetism detection sensor that detects magnetism emitted from a subject; and
a display section that displays a state of the magnetism detected with the magnetism detection sensor,
wherein the magnetism detection sensor is the magnetism detection sensor according to claim 5.

16. A magnetism measurement apparatus comprising:
a magnetism detection sensor that detects magnetism emitted from a subject; and
a display section that displays a state of the magnetism detected with the magnetism detection sensor,
wherein the magnetism detection sensor is the magnetism detection sensor according to claim 6.

17. A magnetism measurement apparatus comprising:
a magnetism detection sensor that detects magnetism emitted from a subject; and
a display section that displays a state of the magnetism detected with the magnetism detection sensor,
wherein the magnetism detection sensor is the magnetism detection sensor according to claim 7.

18. A magnetism measurement apparatus comprising:
a magnetism detection sensor that detects magnetism emitted from a subject; and
a display section that displays a state of the magnetism detected with the magnetism detection sensor,
wherein the magnetism detection sensor is the magnetism detection sensor according to claim 8.

19. A magnetism measurement apparatus comprising:
a magnetism detection sensor that detects magnetism emitted from a subject; and
a display section that displays a state of the magnetism detected with the magnetism detection sensor,
wherein the magnetism detection sensor is the magnetism detection sensor according to claim 9.

20. A magnetism measurement apparatus comprising:
a magnetism detection sensor that detects magnetism emitted from a subject; and
a display section that displays a state of the magnetism detected with the magnetism detection sensor,
wherein the magnetism detection sensor is the magnetism detection sensor according to claim 10.
